(19) United States
(12) Patent Application Publication
(10) Pub. No.: US 2022/0028715 A1
(43) Pub. Date: Jan. 27, 2022

(54) A COMPONENT HANDLING ASSEMBLY

(71) Applicant: ISMECA SEMICONDUCTOR HOLDING SA, La Chaux-De-Fonds (CH)

(72) Inventors: Marco Manuel DE JESUS MENDES NUNES, La Chaux-de-Fonds (CH); Giovanni PALMISANO, La Chaux-de-Fonds (CH); Rémi Eric Patrice TAILLARD, Villers-le-Lac (FR); Thierry EME, Villers-le-Lac (FR)

(73) Assignee: ISMECA SEMICONDUCTOR HOLDING SA, La Chaux-De-Fonds (CH)

(21) Appl. No.: 17/290,711

(22) PCT Filed: Dec. 5, 2019
(86) PCT No.: PCT/IB2019/060486

§ 371 Date: Apr. 30, 2021

(51) Int. Cl. H01L 21/67; H01L 21/683; B65G 47/91

(52) U.S. Cl. CPC H01L 21/67271; B65G 47/91; H01L 21/6838

(57) ABSTRACT

According to the present invention there is provided a component handling assembly which comprises, a transport system which comprises a track, and a plurality of shuttles, wherein each of said shuttles can be driven individually and independently of one another along the track; and wherein each of said shuttles comprise a pick-up-head which can hold a component; a plurality of stations located proximate to the track, said plurality of stations comprising, a picking station at which the pickup head on a shuttle can pick components from a tray located in said picking station; at least one vision inspection station, which comprises one or more cameras, at which a component which has been picked from the picking station and transported to the vision inspection station can be inspected; and at least one of, a placing station at which the pickup head on a shuttle can place a component onto a tray, and/or, a tape station at which the pickup head on a shuttle can place a component into a pocket of a tape.

### FIELD OF THE INVENTION

The present invention concerns a component handling assembly and in particular a component handling assembly which comprises: a plurality of shuttles which can each move independently of one another along a track, wherein each of the shuttles comprise a pick-up-head which can hold a component; a picking station at which the pickup head on a shuttle can pick components; a vision inspection station wherein a component held by the pickup head on a shuttle can be inspected; and at least one of, a placing station which comprise at least one tray into which components can be delivered by the pickup head on a shuttle, and/or a tape station which comprises a tape which comprises pockets into which the pickup head of a shuttle can place a component.

### DESCRIPTION OF RELATED ART

In existing component handling assemblies processing steps, such as picking components from a tray, placing components onto a tray, sorting rejected components from tray to tray or placing components into pockets in a tape, are executed at fixed positions within the assembly. As a result delays occur due to the necessity to replace the rejected devices by good devices in a tray; the necessity to replace trays, which supply components for picking at the picking station, which have become empty; the necessity to replace trays which are to receive components, which have become full; and/or the necessity to replace tapes (which have pockets which can receive components) which have become full. The delays result in reduced flow (continuity) within the assembly, and thus result in reduced through-put.

It is an aim of the present invention to obviate or mitigate at least some of the above-mentioned disadvantages associated with existing component handling assemblies.

### BRIEF SUMMARY OF THE INVENTION

According to the invention, these aims are achieved by means of an assembly having the features recited in the independent claim; wherein the dependent claims recite optional features of preferred embodiments.

### BRIEF DESCRIPTION OF THE DRAWINGS

The invention will be better understood with the aid of the description of an embodiment given by way of example and illustrated by the figures, in which:

FIG. 1a shows a plan view of a component handling assembly according to one embodiment of the present invention; FIG. 1b, shows a plan view of one of the shuttles which can be used in the component handling assembly of FIG. 1a;

FIG. 2a provides a perspective view of an embodiment of the component handling assembly of FIG. 1a which comprises one possible implementation of the vacuum system; FIG. 2b provides a magnified view of a shuttle and its respective vacuum inlet; FIG. 2c shows a cross section of vacuum ring 103 of said component handling assembly;

FIG. 3a provides a perspective view of an embodiment of the component handling assembly which comprises another possible implementation of the vacuum system; FIG. 3b provides a perspective view of a shuttle which is used in said component handling assembly embodiment of FIG. 3a; FIG. 3c provides a plan view of the vacuum system which is used in said component handling assembly embodiment of FIG. 3a; and FIG. 3d provides a perspective cross-sectional view of a part of the vacuum system which is used in said component handling assembly embodiment of FIG. 3a;

FIG. 4 provides a longitudinal section view of a sliding member of the shuttle used in said component handling assembly embodiment of FIG. 3a;

FIG. 5 provides a cross sectional view of the sliding member of the shuttle and portion of the plate member used in said component handling assembly embodiment of FIG. 3a;

FIG. 6a provides and perspective view of a component handling assembly which comprises yet another possible implementation of the vacuum system; FIG. 6b provides a side view of a part of the vacuum system which is used in said component handling assembly embodiment of FIG. 6a and a perspective view of a shuttle which is used in said component handling assembly embodiment of FIG. 6a; FIG. 6c provides a plan view of the vacuum system which is used in said component handling assembly embodiment of FIG. 6a; and FIG. 6d provides a partial cross section view of a part of the vacuum system which is used in said component handling assembly embodiment of FIG. 6a and a perspective view of a shuttle which is used in the vacuum system which is used in said component handling assembly embodiment of FIG. 6a; and FIG. 6e provides a cross sectional view of a part of the vacuum system which is used in said component handling assembly embodiment of FIG. 6a

FIG. 7 provides a cross sectional view of a part of the vacuum system which is used in said component handling assembly embodiment of FIG. 6a and a perspective view of a carriage of the shuttle which is used in said component handling assembly embodiment of FIG. 6a.

### DETAILED DESCRIPTION OF POSSIBLE EMBODIMENTS OF THE INVENTION

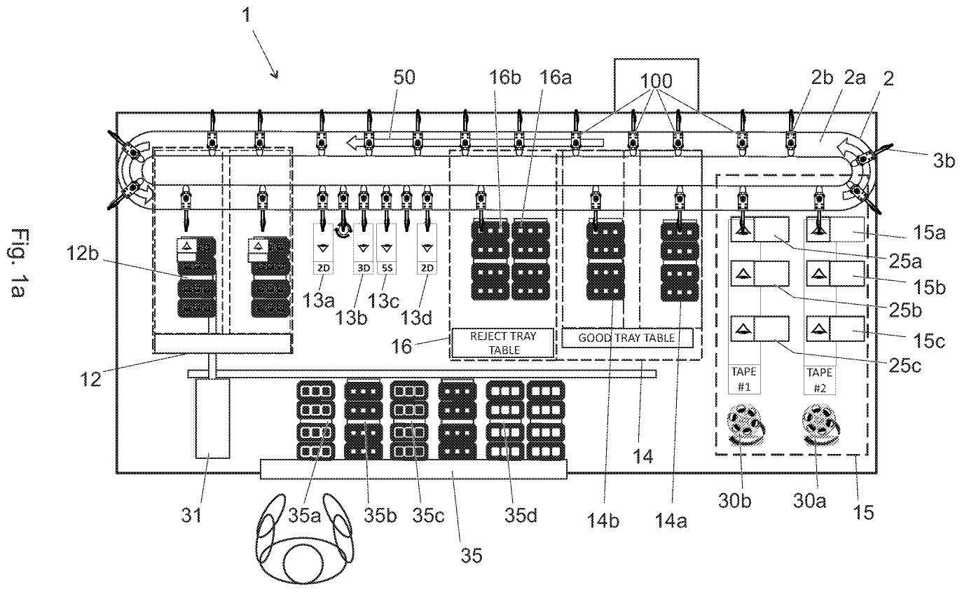

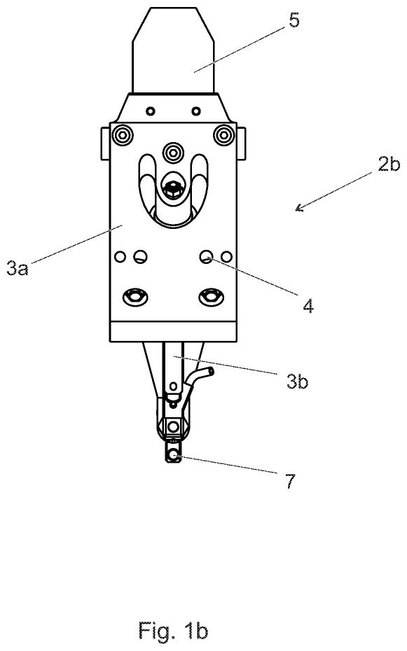

FIG. 1a shows a plan view of a component handling assembly 1 according to one embodiment of the present invention.

The component handling assembly 1 comprises, a transport system 2 which comprises a track 2a, and a plurality of shuttles 2b. The transport system is configured such that each of said shuttles 2b can be driven individually and independently of one another along the track 2a. Such a transport system 2 is known in the art and its implementation may take any suitable form: for example U.S. Pat. No. 9,533,785 discloses a device for transporting objects, and the transport system 2 of the present invention may be implemented in the same or similar manner to the device disclosed in U.S. Pat. No. 9,533,785. However the only essential features of the transport system 2 is that it comprise some sort of track 2a, and a plurality of shuttles 2b; and each of said shuttles 2b can be driven individually and independently of one another along the track 2a. In FIG. 1a the direction of movement of the shuttles 2b on the track is shown by arrow 50; all of the shuttles 2b move in the same direction on the track 2a.

It should be understood that the track 2a may be of any shape. Most preferably the track is configured to be in the form of a loop (i.e. follows a loop), as is the case in the track 2a of the component handling assembly 1 shown in FIG. 1a. It should be understood that the track could, for example, in the form of a circle (i.e. the track may be annular-shaped, or circular-shaped), or in the form of an oval (i.e. oval-shaped); or in the form of a rectangle (i.e. rectangular-shaped), or in the form of a square (i.e. square-shaped), or may be in a form which has two straight sections connected by two curved sections.

Importantly, in this invention, each of said shuttles 2b comprises at least one pickup head 3b which can hold a component. In this embodiment each of said shuttles 2b comprises one pickup head 3b which can hold a component. However, it should be understood that some of, or all of, said shuttles 2b could comprise any number of pickup heads (e.g. more than one pickup head 3b); for example said plurality of shuttles 2b may comprise shuttles 2b which comprise two pickup heads. Each of the pickup-heads 3b on a shuttle 2b is configured to hold a component using vacuum; said vacuum is supplied to the pickup-heads 3b by a vacuum system 100. As will be described in more detail below the vacuum system 100 can various different implementations (vacuum system 100a-c) without departing from the scope of the invention. However it should be understood that every component handling assembly embodiment, described in the present description, has the features which are illustrated in FIGS. 1a and 1 b.

As will be described in more detail below the design of said shuttles 2b will vary depending on the implementation of the vacuum system 100. However for every implementation (vacuum system 100a-c) of the vacuum system 100 each of said shuttles 2b comprise in each vacuum system implementation 100a-c, will comprise at least the features which are illustrated in FIG. 1b. FIG. 1b shows a plan view of the portion of a shuttle 2b which can be used in the component handling assembly 1; the shuttle 2b comprises one pickup head 3b and the pickup-head 3b on each shuttle 2b is configured to hold a component using vacuum. Each shuttle 2b comprises a carriage 3a which cooperates with the track 2a and is configured to move along the track 2a; the pickup head 3b is attached to the carriage 3a. As mentioned the pickup head 3b is configured to hold a component using vacuum, and the opening 7 on the pickup head through which the vacuum is provided to the surface of the component, can be seen in FIG. 1b.

The carriage 3a comprises magnets 4 which can be used to control the speed of the movement of the shuttle 2b along the track 2a. The track 2a typically comprises electro magnets (located along the track 2a) which can be selectively activated to provide a magnetic field; when the electro magnets on the part of the track which is occupied by a shuttle 2b are activated, then the magnets on the track 2a repel the magnets 4 on the shuttle 2b to push the shuttle 2b off the track 2a also serve to move the ‘floating’ shuttle 2b along the track 2a (similar to maglev). Also the carriage 3a comprises an encoder and/or sensor 5 which can be used to detect the position of said shuttle 2b on the track 2a, thus enabling the position of each shuttle 2b relative to other shuttles 2b on the track to be determined, and thus enabling to control the movement (i.e. speed) of the shuttles 2b to avoid the shuttles 2b on the track 2a from colliding with one another (in the same manner as is done the device disclosed in U.S. Pat. No. 9,533,785).

As mentioned above, the component handling assembly 1 comprises a vacuum system 100. The vacuum system 100 is operable to supply vacuum to the pickup head 3b of each shuttle 2b in the assembly; moreover the vacuum system 100 is operable to supply vacuum to the pickup head 3b of each shuttle 2b in the assembly as those shuttles 2b move around the track 2a. It should be understood that the vacuum system 100 may be implemented in various different ways giving rise to a variety of different assembly 100 embodiments. Three different vacuum systems 100a-c will be described, giving rise to corresponding three assembly embodiments:

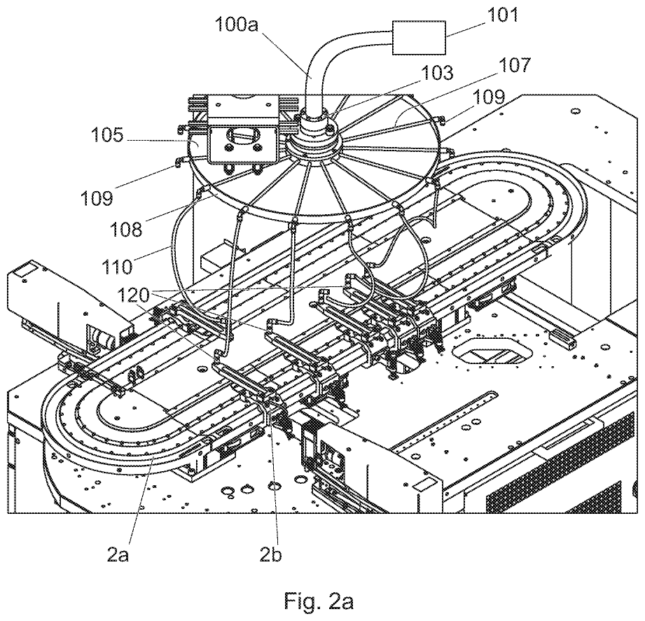

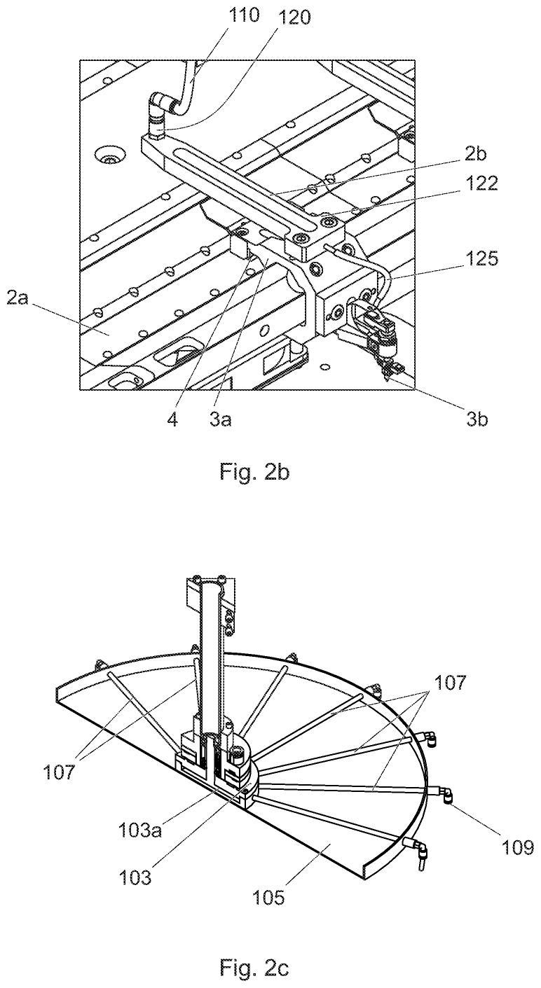

FIG. 2a provides a perspective view of the assembly 100 having a first exemplary implementation of the vacuum system 100; assembly 100 comprises a vacuum system 100a.

The vacuum system 100a of the assembly 100 shown in FIG. 2a comprises a vacuum generating means 101 which is operable to generate a vacuum; a vacuum ring 103 which defines a chamber 103a (as can be seen in FIG. 2c which shows a cross sectional view of the vacuum ring 103), wherein the chamber 103a is fluidly connected to the vacuum generating means so that vacuum generated by the vacuum generating means will create a vacuum in the chamber 103a of the vacuum ring 103; a rotatable disk 105 (which can rotate about a rotation axis 105b) which comprises a plurality of primary conduits 107, each primary conduit 107 being fluidly connected to the chamber 103a of the vacuum ring 103 and arranged to extend radially from the vacuum ring 103. In one embodiment each of the plurality of primary conduits 107 are integral to the rotatable disk 105, whereas in another embodiment each of the primary conduits 107 are defined by a respective conduit and the conduit is attached to the rotatable disk 105.

FIG. 2c shows a cross section of vacuum ring 103. Referring to FIGS. 2a and 2c, it can be seen that in this embodiment the vacuum ring 103 defines a single chamber 103a, and each of the plurality of primary conduits 107 is fluidly connected to that single chamber. Importantly the rotatable disk 105 can rotate and each of the plurality of primary conduits 107 will remain, throughout a complete rotation of the disk 105, continuously, fluidly connected to that single chamber defined by the vacuum ring 103 (this ensures that there is no interruption of the supply of vacuum to each of the primary conduits 107 even as the rotatable disk 105 rotates about the rotation axis 105b).

In one embodiment rotatable disk 105 can freewheel about the rotation axis 105b; however in another embodiment the component handling assembly 1 further comprises a drive motor which can drive the rotatable disk 105 to rotate about the rotation axis 105b.

The vacuum system 100a further comprises, a plurality of outlets 109 arranged at the peripheral of the rotatable disk 105 and wherein each primary conduit 107 is fluidly connected to a respective outlet 109; and a plurality of secondary conduits 110, wherein each secondary conduit 110 is fluidly connected between a respective outlet 109 and a respective vacuum inlet 120 on a respective shuttle 2b. Most preferably each of the secondary conduits 110 is formed of flexible material, for example each secondary conduit 110 may be defined by a respective rubber tube. In an embodiment each of the secondary conduits 110 is formed of a material which is both an elastic and flexible, so that each secondary conduit 110 can be stretched to increase in length, and can elastically return to its original length after the force which stretches the secondary conduit is removed.

FIG. 2b provides a magnified view of a shuttle 2b which is used in the assembly 100 which comprises the vacuum system 100a. The shuttle 2b comprises a vacuum inlet 120. The vacuum inlet 120 of each respective shuttle 2a is fluidly connected to the pickup head 3b of that shuttle 2a. In this embodiment the vacuum inlet 120 is fluidly connected, via a chamber defined inside an upper member 122 of the shuttle 2a, to an intermediate conduit 125; and wherein the intermediate conduit 125 is fluidly connected to the pickup head 3b. However, it should be understood the vacuum inlet 120 of a shuttle 2a can be fluidly connected to the pickup head 3b of that shuttle 2a using any other suitable means.

The vacuum system 100a can operate to provide vacuum to the pickup head 3b on each shuttle 2a so that each shuttle 2b can hold a respective component at the pickup head 3b by vacuum: the vacuum generating means 101 is operated to generate a vacuum; the generated vacuum will create vacuum within the single chamber defined by the vacuum ring 103 which in turn creates a vacuum within each of the primary conduits 107 in the rotatable disk 105 (since each of primary conduits 107 is fluidly connected to the same single chamber defined by the vacuum ring 103, and since the vacuum generated by the vacuum generating means 101 is continuous, the vacuum in each of the primary conduits 107 will be continuous even as the rotatable disk 105 rotates); the vacuum in each of the primary conduits 107 in turn creates a vacuum at each of the plurality of outlets 109 at the peripheral of the rotatable disk 105; the vacuum created at each of the plurality of outlets 109 in turn creates a vacuum in each of the plurality of secondary conduits 110, which in turn creates a vacuum at each of the vacuum inlets 120 of each respective shuttle 2b; the vacuum at the vacuum inlet 120 of each respective shuttle 2a in turn creates a vacuum at the pickup head 3b of that respective shuttle 2a and the vacuum at the pickup head 3b of that respective shuttle 2a is used to hold a component on the pickup head 3b of that shuttle 2a.

As mentioned in one embodiment the rotatable disk 105 is configured so that it freewheels about a rotation axis 105b; in such an embodiment, when the shuttles 2a move around the track 2a, the secondary conduits 110 (each of which is connected at one end to a respective outlet 109 at the peripheral of the rotatable disk 105 and connected at their opposite end to a respective shuttle 2a (specifically to a vacuum inlet 120 of the shuttle 2a)) will pull on the rotatable disk 105 (specifically will pull on respective outlets 109 at the peripheral of the rotatable disk 105); the pulling force applied by the secondary conduits 110 will cause the rotatable disk 105 to rotate (i.e. freewheel) about the rotation axis 105b so that the rotatable disk 105. Since the rotatable disk 105 is configured to freewheel the rotatable disk 105 does not hold back the shuttles 2a from moving around the track 2b; specifically the rotatable disk 105 will freewheel about the rotation axis 105b, rotating in the same direction the shuttles move around the track 2a (i.e. clockwise or anticlockwise) and at a speed dictated by the pulling force which the secondary conduits 110 apply to the rotatable disk 105. In this way the vacuum system 100a can continue to provide vacuum to the pickup heads 3b of each shuttle 2a even as the shuttles 2a move around the track 2a. Furthermore, the secondary conduits 110 do not become entangled as the shuttles 2a move around the track 2a.

As mentioned in another embodiment the component handling assembly 1 further comprises a drive motor which can drive the rotatable disk 105 to rotate about the rotation axis 105b; in other words in this embodiment the movement of the rotatable disk 105 to rotate about the rotation axis 105b is motorized (unlike the previously mentioned embodiment in which the rotatable disk 105 was configured to freewheel about the rotation axis 105b). In this embodiment the drive motor is operated to rotate the rotatable disk 105 about the rotation axis 105b, in the same direction (i.e. clockwise or anticlockwise) in which the shuttles 2b move around the track 2a, and at a speed which ensures that the secondary conduits 110 do not restrain (i.e. hold back) the shuttles 2b from moving on the track 2a (i.e. to ensure that each respective secondary conduit 110 does not apply a force to the respective shuttle 2b in a direction opposite to which that shuttle is moving around the track 2a); this can be achieved for example, by rotating the rotatable disk 105 about the rotation axis 105b at a speed which ensures that the plurality of outlets 109 at the peripheral of the rotatable disk 105 substantially keeps pace with the moving shuttles 2b. In this way the vacuum system 100 can continue to provide vacuum to the pickup heads 3b of each shuttle 2a even as the shuttles 2a move around the track 2a. Furthermore, the secondary conduits 110 do not become entangled as the shuttles 2a move around the track 2a.

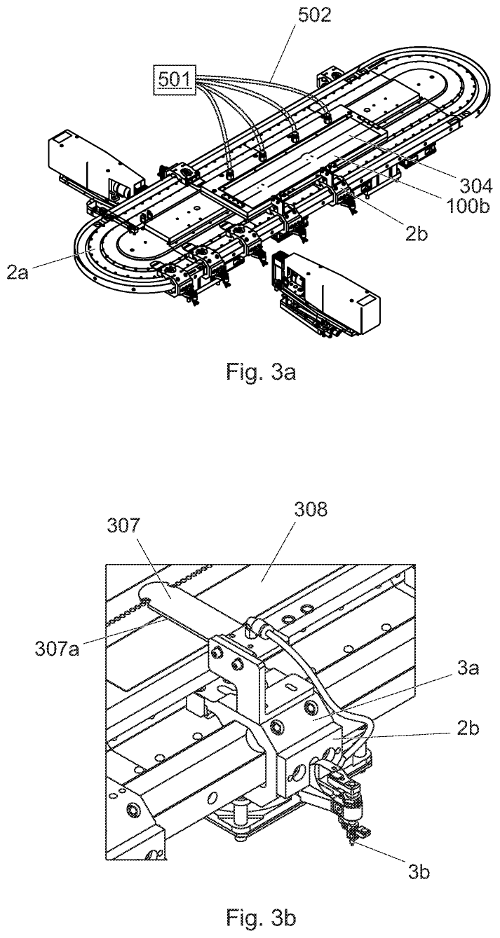

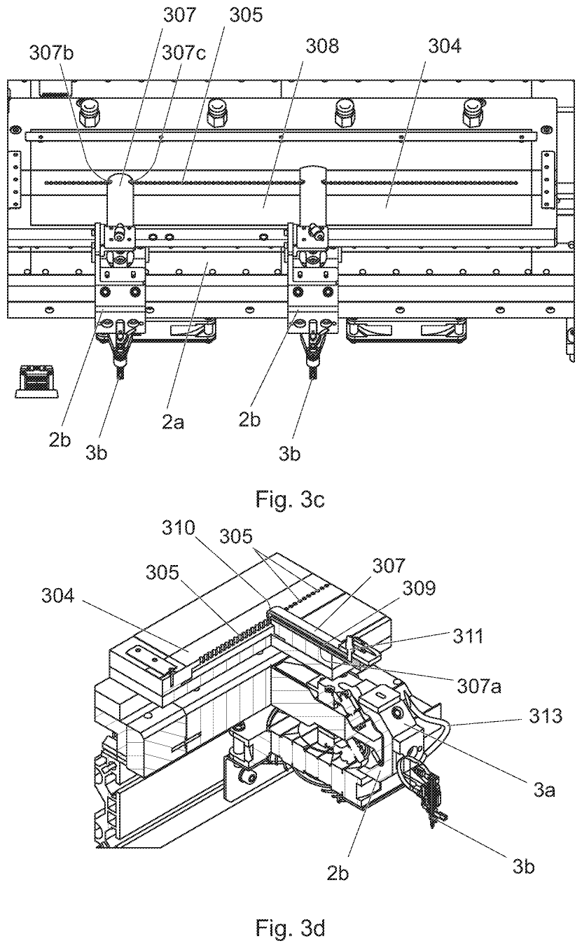

FIG. 3a provides a perspective view of the assembly 100 having a second exemplary implementation of the vacuum system 100; assembly 100 of FIG. 3a comprises a vacuum system 100b. FIG. 3b provides a perspective view of a shuttle 2b which is used in said component handling assembly embodiment which comprises the vacuum system 100b; FIG. 3c provides a plan view of a portion of the vacuum system 100b; and FIG. 3d provides a perspective cross-sectional view of a part of the vacuum system 100b and a perspective view of a shuttle 2b used in said component handling assembly embodiment which comprises the vacuum system 100b.

Referring to FIGS. 3a-d, the vacuum system 100b comprises a vacuum generating means 501 which is selectively operable to generate a vacuum; a vacuum chamber 303, which is fluidly connected to the vacuum generating means 501 (by way of conduits 502), so that vacuum generated by the vacuum generating means 501 will create a vacuum in the vacuum chamber 303; a plate member 304 having one or more openings 305 defined therein, wherein said one or more openings 305 are each fluidly connected to the vacuum chamber 303. In this example the plate member 304 has a plurality of openings 305 defined therein wherein the plurality of openings 305 are arranged in succession, parallel to the track 2a. (In another embodiment, instead of a plurality of openings 305 arranged in succession, the plate member 304 may have a single opening (i.e. a continuous channel) which extends parallel to the track 2a).

For clarity FIG. 3a shows the vacuum system 100b extending along only a portion of the track 2a (e.g. the plurality of openings 305 are arranged in succession along only a portion of the track 2a); however it should be understood that the vacuum system 100b preferably extends along the whole length of the track 2a. In other words, preferably, the plate member 304 has openings 305 defined therein (each of which is fluidly connected to the vacuum chamber 303) which are located along full length of the track 2a (i.e. the plurality of openings 305 are arranged in succession, around the full loop of the track 2a; for example, preferably the plate member 304 is larger than is shown in FIG. 3a, preferably the plate member 304 is large enough to extend along the along the whole length around the inside of (or outside of) the loop of the track 2a so that the plurality of openings 305 are arranged in succession, to form a loop which is inside the loop of the track, parallel to the track 2a).

In the embodiment of the component handling assembly which comprises the vacuum system 100b, each of said plurality of shuttles 2b comprise a sliding member 307 which is arranged to about a surface 308 (preferably a flat surface 308) of the plate member 304 and is configured to slide over said surface 308 as the shuttles 2b moves along the track 2a. As shown in FIG. 3d said sliding member 307 of each shuttle 2b has a channel 309 defined therein, wherein the channel 309 has an inlet 310 and an outlet 311, wherein said outlet 311 is fluidly connected to the pickup head 3b of the shuttle 2b (In this example the said outlet 311 it fluidly connected to an output spout 312, and the output spout 312 is in turn fluidly connected via a conduit 313 to the pickup head 3b of the shuttle 2b. However it should be understood that the said outlet 311 can be fluidly connected to the pickup head 3b of the shuttle 2b using any means). The inlet 310 is aligned over, at least one of, said plurality of openings 305 defined in the plate member 304; importantly the inlet remains aligned over at least one of said plurality of openings 305 defined in the plate member 304 as the sliding member 307 slides along said surface 308 of the plate member 304, as the shuttle 2b moves along the track 2a, so that vacuum can be supplied to the pickup head 3b of said shuttle 2b as the shuttle 2b moves around the track 2a.

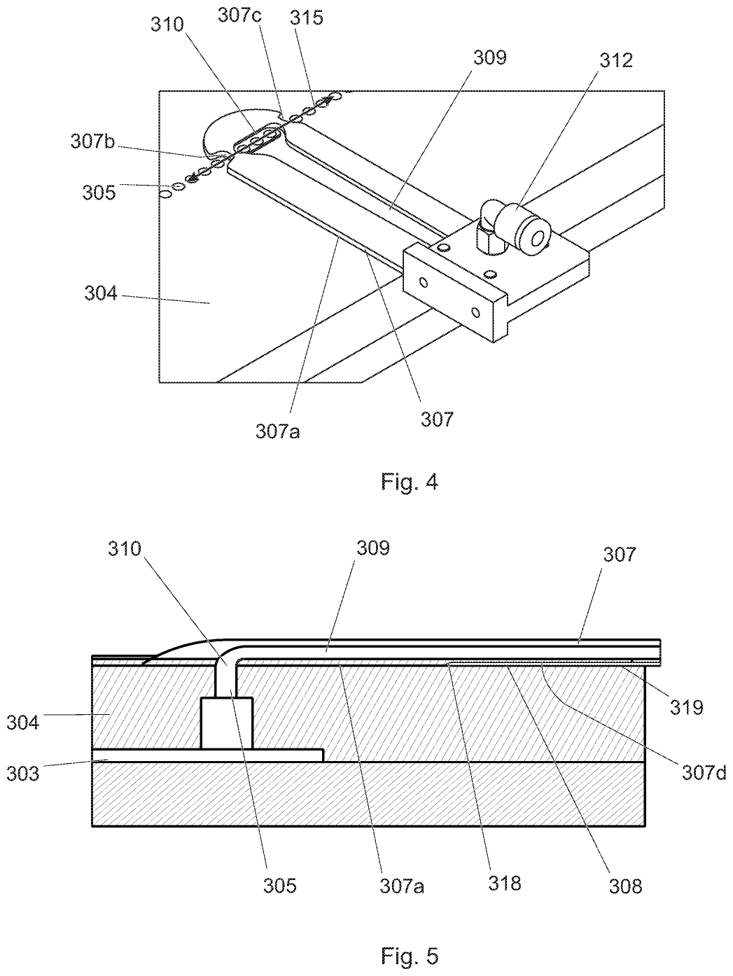

FIG. 4 provides a longitudinal section view of the sliding member 307 of the shuttle 2a; as shown the inlet 310 is large enough to extend over more than one of said openings 305 defined in the plate member 304; specifically, in this example the inlet 310 extends over three successive openings 305 defined in the plate member 307 (however the inlet 310 could be configured to extend over any number of successive openings 305 defined in the plate member 307, for example, the inlet 310 could be configured to extend over two successive openings 305 defined in the plate member 307). Most preferably, in the embodiment in which the plate member 304 has a plurality of openings 305 defined therein, the inlet 310 of the sliding member 307 is large enough to extend over at least two of said openings (e.g. the inlet is longer than, or has a length at least equal to the total length of the diameter of two successive openings); advantageously this will ensure that there is no interruption in the supply of vacuum to the pickup head 3b of said shuttle 2b as the shuttle 2b moves around the track 2a (if the inlet 310 of the sliding member 307 would be sized to extend over just one single opening, then there would be an interruption in the supply of vacuum to the pickup head 3b of that shuttle 2b as the sliding member 307 slides from a position where the inlet 310 is aligned over one opening defined in the plate member 304 to the position where the inlet 310 aligned over the next successive opening defined in the plate member 304.)

As can be best seen in FIGS. 3b and 3d, and FIG. 4, the sliding member 307 is semi-cylindrical-shaped with a flat surface 307a of the sliding member 307 being arranged to abut the surface 308 of the plate member 304; the inlet 310 is defined in said flat surface 307a of the sliding member 307. The abutment between the flat surface 307a of the sliding member 307 and the surface 308 of the plate member 304, ensures that little or no vacuum escapes at the interface between the sliding member and plate member 304, and thus ensures that vacuum created in the chamber 303 passes to the channel 309 in the sliding member 307.

Also, as can be seen in FIGS. 3c and 4, each sliding member 307 has curved cut-outs 307b, 307c at opposite sides of the sliding member 307; the curved cut-out 307b, 307c are aligned with and are arranged on opposite sides of the inlet 301, thus the curved cut-outs 307b, 307c and the inlet 310 all lie on the same axis 315. Each of the curved cut-outs 307b, 307c is aligned over said openings 305 defined in the plate member 304.

FIG. 5 shows a cross sectional view of the sliding member 307 and a portion of the plate member 304. As shown the flat surface 307a of the sliding member 307 abuts the surface 308 of the plate member 304. The sliding member 307 further comprises a step 318 which is adjacent the flat surface 307a; the step 318 is at the interface between the flat surface 307a which abuts the surface 308 of the plate member 304 and a secondary surface 307d, which is parallel to the flat surface 307a but which lies on a plane which is higher than the plane of the flat surface 307a so that there is a gap 319 between the secondary surface 307d and the surface 308 of the plate member 304. This gap 319 allows to reduce friction between the sliding member 307 and the plate member 304 so that the sliding member 307 can more easily slide over the plate member 304 as the shuttle 2b moves along the track 2a.

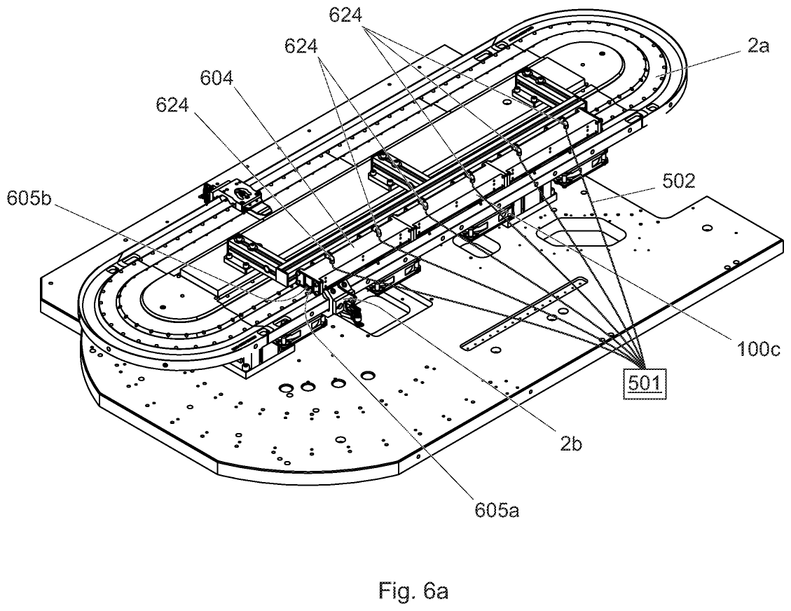

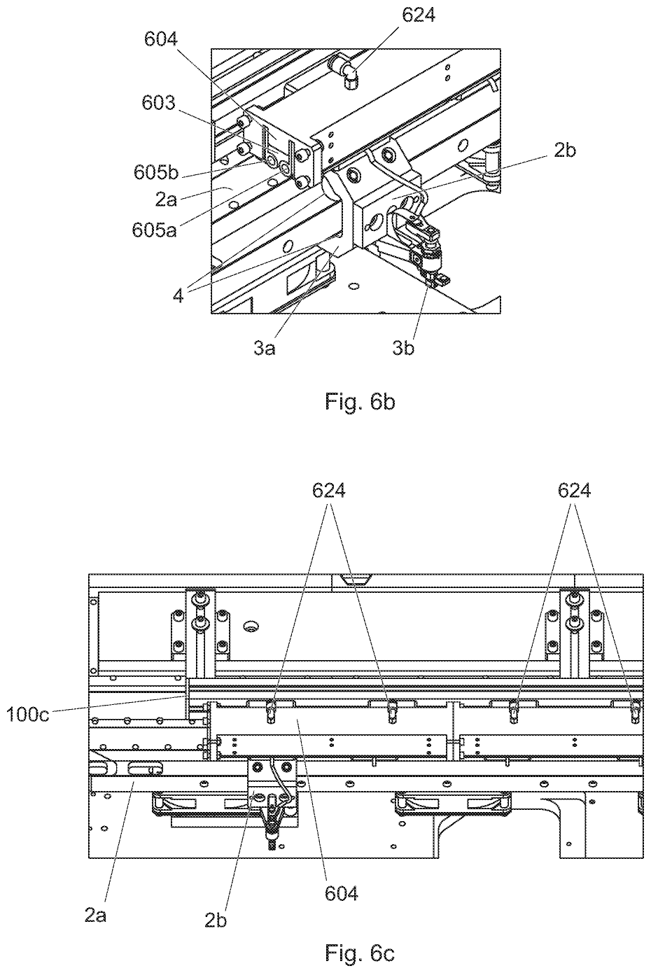

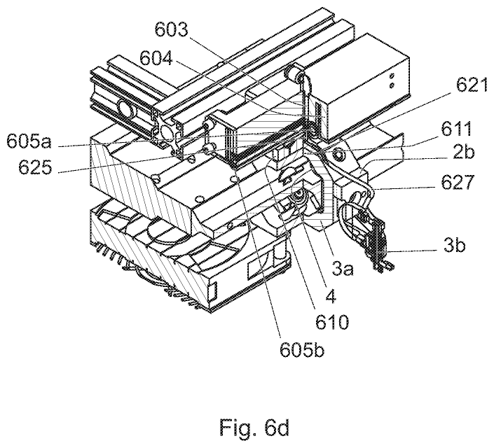

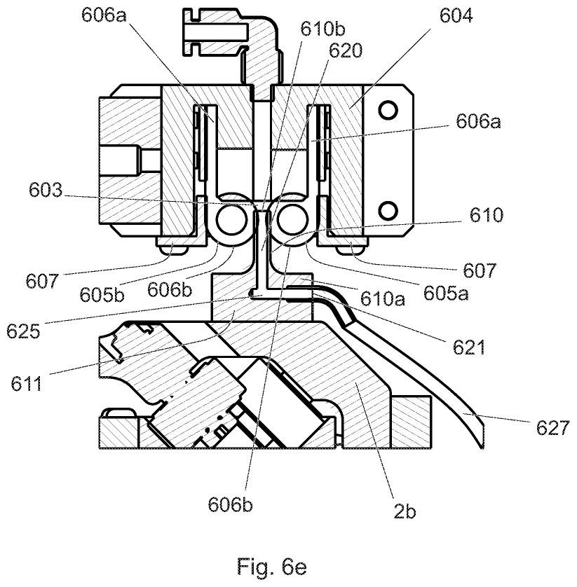

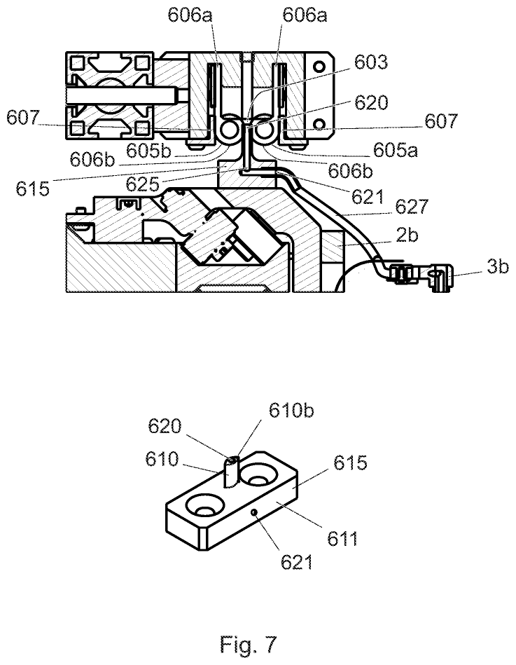

FIG. 6a provides a perspective view of the assembly 100 having a third exemplary implementation of the vacuum system 100; the assembly 100 of FIG. 6a comprises a vacuum system 100c; FIG. 6b provides a perspective side view of a part of the vacuum system 100c and a perspective view of a shuttle 2b which is used in said component handling assembly embodiment which comprise the vacuum system 100c; FIG. 6c provides a plan view of the vacuum system 100c; and FIG. 6d provides a cross section view of a part of the vacuum system 100c and a perspective view of a shuttle 2b which is used in said component handling assembly embodiment which comprise the vacuum system 100c; and FIG. 6e provides a cross sectional view of a part of the vacuum system 100c. FIG. 7 provides a cross sectional view of a part of the vacuum system 100c and a perspective view of the carriage 615 of the shuttle 2b.

Referring to FIGS. 6a-e and FIG. 7, the vacuum system 100c comprises, a vacuum generating means 501 which is selectively operable to generate a vacuum; a vacuum chamber 603, which is fluidly connected to the vacuum generating means 501 (via conduits 502), so that vacuum generated by the vacuum generating means 501 will create a vacuum in the vacuum chamber 603. As can be best seen in FIGS. 6e and 7 the vacuum chamber 603 is defined by a volume which is between an upper plate member 604 and opposing sealing members 605a,b which project below upper plate member 604; each of the opposing sealing members 605a,b have a respective first end 606a which is attached to the upper plate member 604 and a second free end 606b.

For clarity FIG. 6a shows the vacuum system 100c extending along only a portion of the track 2a; however it should be understood that vacuum system 100c preferably extends along the whole length of the track 2a. In other words, preferably, the upper plate member 604 and opposing sealing members 605a,b are located above the track 2a, and extend (preferably parallel to the track 2a), in a loop, over the full length of the track 2a (i.e. extend all the way around the track 2a).

The upper plate member 604 comprises a plurality of vacuum inputs 624 each of which is fluidly connected to the vacuum chamber 603. Each vacuum inputs 624 is fluidly connected to the vacuum generating means 501 (via conduits 502). In this embodiment the plurality of inputs 624 are evenly distributed along the upper plate member 604 so that vacuum supplied by the vacuum generator is substantially evenly distributed in vacuum chamber 603.

The sealing members 605a,b are arranged such that the second free ends 606b of the sealing members 605a,b abut one another to seal the vacuum chamber 603. In this embodiment the second free ends 606b of the sealing members 605a,b are elastically biased towards abutting one another to seal the vacuum chamber 603. The second free end 606b of each sealing member 605a,b is configured to have a circular cross section (however this is not an essential feature of the invention and the second free end 606b may have any suitable shape or configuration). The sealing members 605a,b comprise elastic material so that the second free end 606b of each sealing member 605a,b can be elastically compressed.

In this embodiment the opposing sealing members 605a,b each comprise rubber material—this allows for the second free end 606b to be easily elastically compressed (however it should be understood that the opposing sealing members 605a,b may comprise any suitable material; most preferably at least the second free end 606b of the opposing sealing members 605a,b will comprise elastic and flexible material). Furthermore, in this embodiment the second free ends 606b of each sealing member 605a,b are configured to have a circular cross section; the circular cross section allows for easier compression of the second free ends 606b when a compression force is applied to the second free ends 606b.

In this embodiment the vacuum system 100c further comprise a restrictor members 607, which is arranged adjacent to the respective second free ends 606b of the sealing members 605a,b; the restrictor members 607 restrict the movement of the respective second free ends 606b of the sealing members 605a,b away from one another (however it should be understood that the restrictor members are an optional feature; for example no restrictor members may be provided (with elastic biasing of the opposing sealing members towards abutting one another being used as the only means to restrict the movement of the second free ends 606b of the sealing members 605a,b away from one another; or walls of the upper plate member 604 may be used to restrict the movement of the second free ends 606b of the sealing members 605a,b away from one another).

As can be best seen in FIGS. 6e and 7, each of said plurality of shuttles 2b comprise a carriage 615 having an anchoring portion 611 and a stem portion 610 which has a first end 610a which is attached to the anchoring portion 611 and a second, free, end 610b. The carriage 615 is arranged so that the stem portion 610 projects between the second free ends 606b of the opposing sealing members 605a,b so that the second free end 610b of the stem portion 610 is located within the vacuum chamber 603, and so that the anchoring portion 611 of the carriage is outside of the vacuum chamber 603 below the second free ends 606b of the sealing members 605a,b.

The carriage 615 has a channel 625 defined therein which fluidly connects an inlet 620 and outlet 621; the inlet 620 is defined in the second free end 610b of the stem portion, and the outlet 621 is defined in the anchoring portion 611 of the carriage 615.

The outlet 621 is fluidly connected to the pickup head 3b of the shuttle 2b. In this example the outlet 621 is fluidly connected to the pickup head 3b of the shuttle 2b by means of a conduit 627, however it should be understood that the outlet 621 can be fluidly connected to the pickup head 3b of the shuttle 2b using any suitable means.

Since the second free end 610b of the stem portion 610 is located within the vacuum chamber 603 the inlet 620 fluidly connects the channel 625 with the vacuum chamber 603. The second free end 610b of the stem portion 610 remains continuously located within the vacuum chamber 603 as the shuttle 2b moves along the track 2a; as the shuttle 2b moves along the track 2a the second free end 610b of the stem portion 610 will be moved through the vacuum chamber 603. Thus vacuum can be supplied to the pickup head 3b of said shuttle 2b as the shuttle 2b moves around the track 2b (specifically, the vacuum passes from vacuum chamber 603 into the inlet 620, and to the output 621 via the channel 625 in the carriage 615; the vacuum then passed from output 621 to the pickup head 3b of the shuttle 2b via the conduit 627).

As mentioned, the second free end 610b of the stem portion 610 remains continuously located within the vacuum chamber 603 as the shuttle 2b moves along the track 2a; as the shuttle 2b moves along the track 2a, the second free end 610b of the stem portion 610 is moved through the vacuum chamber 603; the stem portion 610 of the carriage which projects between the second free ends 606b of the opposing sealing members 605a,b compresses successive portions of the second free ends 606b of the opposing sealing members 605a,b as the shuttle 2a moves along the track 2b. When the shuttle 2a occupies a position on the track 2b, the stem portion 610 of the carriage 615 of the shuttle 2b, which projects between the second free ends 606b of the opposing sealing members 605a,b, will compress the portion of the second free ends 606b of the opposing sealing members 605a,b at said position; the portion of the second free ends 606b of the opposing sealing members 605a,b at said position occupied by the stem portion 610 will abut opposing sides of the stem portion 610, to form a substantially fluid-tight abutment so that vacuum in the vacuum chamber 603 is prevented from escaping at the interface between the stem portion 610 and the opposing sealing members 605a,b.

Furthermore, since the second free ends 606b of the opposing sealing members 605a,b are elastically biased towards abutting one another, the portions of the second free ends 606b of the opposing sealing members 605a,b which are on either side of the position occupied by the stem portion 610 of the carriage 615, will abut one another to form a substantially fluid-tight abutment to seal the vacuum chamber 603.

Referring to FIG. 1a again, the component handling assembly 1 further comprises a plurality of stations located proximate to the track 2a. It should be understood that the station may take any suitable form. In this example said plurality of stations comprise, a picking station 12, a plurality of vision inspection stations 13a-d, a placing station 14, and a tape station 15, and a rejection station 16. It should be understood that the assembly 1 may comprise any number of vision inspection stations, for example the assembly 1 may only comprise a single vision inspection station. Also it will be understood that the assembly may comprise only one of a placing station or a tape station.

The picking station 12 is a station at which the pickup head 3b on a shuttle 2b can pick components from a tray 12a, 12b located in said picking station 12. In this example, the picking station 12 comprises two trays: a first tray 12a, and a second tray 12b; each tray comprises components which are to be delivered to the rejection station 16, placing station 14 or tape station 15. In one example, a shuttle 2b which arrives at the picking station 12 is paused at a position on the track 2a which is opposite the first tray 12a and the pickup head on that shuttle 2b then picks a component from the first tray 12a; this happens for each shuttle 2b which arrives in the picking station 12 until all of the components in the first tray 12a have been picked (i.e. until the first tray 12a is empty). When the first tray 12a is empty, the shuttle 2b which subsequently arrives at the picking station 12 is paused at a position on the track 2a which is opposite the second tray 12b and the pickup head on that shuttle 2b then picks a component from the second tray 12b; this happens for each shuttle 2b which arrives in the picking station 12 until all of the components in the second tray 12b have been picked (i.e. until the second tray 12b is empty). While the components are being picked from the second tray 12b, the empty first tray 12a is replaced by another tray which is full of components; thus when the second tray 12b is empty components are again picked from first tray 12a. Advantageously the assembly 1 does not need to be interrupted when a tray at the picking station 12 becomes empty.

The plurality of vision inspection stations 13a-d are used to inspect components for defects. Specifically the plurality of vision inspection stations 13a-d comprises one or more cameras which capture images of the component (e.g. an image of a surface of the component) and these images are then processed to detect if defects are present—e.g. cracks on the surface of the component, damage to pins, contact pads or balls on the component etc). Most preferably each of the plurality of vision inspection stations 13a-d is configured to carry out inspection of the component, while the component is held by the component handling head 3b of the respective shuttle 2b. In this example the assembly 1 comprises, a first 2D inspection station 13a, a 3D inspection station 13b, a 5S inspection station 13c, and a second 2D inspection station 13d.

At the first 2D inspection station 13a inspection of a component held on a pickup head of a shuttle 2b is carried out by a camera which provides two-dimensional images. For example, lead(s) of the component, contact pad(s) of the component, and/or 2-D ball(s) provided on the surface of the component, may be inspected using the camera which provide two-dimensional images. Specifically said lead(s), contact pad(s), and/or 2-D ball(s) provided on the surface of the component, may be inspected for defects such as breaks, bending or cracks.

At the 3D inspection station 13b inspection of a component held on a pickup head of a shuttle 2b is carried out using cameras which provide three-dimensional images. For example, the height of the component can be inspected at this station 13b; the coplanarity of leads of the component, and/or the coplanarity of contact pads of the component, and/or the coplanarity of balls of the component, can be inspected for defects, using said cameras which provide three-dimensional images. For example, a defect could be that the contact pads of a component are not coplanar;

and/or the lead(s) of a component are not coplanar; and/or the balls of component are not coplanar; and/or that the height of the component is insufficient due to a depression or damage on a surface of the component, for instance.

At the 5-S inspection station 13c there is provided an optical device and inspection module as described in application WO2004079427. Specifically the 5-S inspection station 13c is a five-side inspection station which is configured (by means of cameras and prisms and/or mirrors) to provide images of at least five surfaces of the component simultaneously. Here said five surfaces are inspected for defects such as cracks or damage etc.

If a defect in a component is detected upon inspection at any one of the first 2D inspection station 13a, the 3D inspection station 13b, and/or the 5-S inspection station 13c, then that component is considered to be a defective component, otherwise it is considered to be a good component.

The second 2D inspection station 13d comprises a camera which is used to detect the current position and current orientation of the component on the pickup head of the shuttle 2b. The second 2D inspection station 13d preferably further comprises a recentering module which moves the component from its current position and current orientation on the pickup head into a predefined position and predefined orientation on the pickup head. It would be understood that the rotation of the component can be done on a recentering module or with an embodiment integrated to the pickup head itself actuated by an external motor. The predefined position and orientation facilitates the pickup head to be able to place the component into a tray at the placing station or rejection station, or into a pocket of a tape at the tape station; it reduces the risk for damaging (e.g. bending) leads of a component damaging balls of a component when placing the component into a tray at the placing station or rejection station, or into a pocket of a tape at the tape station.

As mentioned the assembly 1 further comprises a placing station 14 and a tape station 15, and rejection station 16.

The rejection station 16 comprises a first reject tray 16a and a second reject tray 16b. If a component was determined at an inspection station 13a-d to have a defect (i.e. referred to hereafter as a defective component), then the shuttle 2b which is carrying that defective component will be stopped opposite to the first reject tray 16a, and the handling head 3b on the shuttle 2b will place the defective component into the first reject tray 16a; the same steps will occurs for each subsequent shuttle 2b which arrives at the reject station 16 and which carries a defective component, until the first reject tray 16a is full.

When the first reject tray 16a is full of defective components then shuttles 2b which carrying a defective component, which arrive into the rejection station 16, will be stopped opposite to the second reject tray 16b, and the handling head 3b on the respective shuttles 2b will place the respective defective component into the second reject tray 16b. In the meantime the first reject tray 16a which is full of defective components is replaced with an empty first reject tray so that when the second reject tray 16b is full of defective components the shuttles carrying defective components place these defective components into the empty first reject tray. Likewise before the empty first reject tray becomes full of defective components, in the meantime, the full second reject tray is replaced with an empty second reject tray. Advantageously the assembly 1 does not need to be interrupted when a reject tray at the rejection station 16 becomes full of defective components.

If a component was determined at an inspection station 13a-d to have no defect (i.e. referred to hereafter as good component), then that good component is placed into a tray in the placing station 14 or is placed into a pocket of a tape in the tape station 15.

In this example the assembly 1 can be selectively operated in a first mode of operation or a second mode of operation (a user can select the operation mode); this is because the assembly in this example has both a placing station 14 and a tape station 15. However in another embodiment the assembly has either a placing station or taping station (not both), in such a case there will not be the option to operate in two modes, rather the assembly will only operate in either the first mode if the assembly comprises a placing station; and will only operate in the second mode if the assembly comprises a tape station.

In all modes of operation the vacuum system 100 will be operated to provide vacuum to the pickup head of each shuttle 2b in the assembly.

In the first mode of operation a component which has been picked from the picking station 12 and has passed through the vision inspection stations 13a-d and is determined to be a good component, is finally placed by the pickup head on the shuttle 2b in a tray in the placing station 14; in the second mode of a component which has been picked from the picking station 12 and has passed through the vision inspection stations 13a-d and is determined to be a good component, is finally placed by the pickup head on the shuttle 2b into a pocket of a tape in the tape station 15. So whether a good component is finally placed by the pickup head on the shuttle 2b into a tray in the placing station 14 or into a pocket of a tape at the tape station 15 depends on the mode of operation of the assembly 1 which the user selected.

The placing station 14 comprises at least two trays, such that when one of the trays is full of good component, the pickup head 3b on a shuttle 2b can place components into said other tray located in said picking station, while the full tray is being replaced with another empty tray. In this example the placing station 14 comprises, a first good tray 14a, and a second good tray 14b, into which the pickup head on a shuttle 2b can place component which is holds.

If a component was determined at an inspection station 13a-d to have a no defect (i.e. is determined to be a good component), and the assembly is in its first mode of operation, then the shuttle 2b which is carrying that good component will be stopped opposite to the first good tray 14a, and the handling head 3b on the shuttle 2b will place the good component into the first good tray 14a; the same steps will occur for each subsequent shuttle 2b which arrives at the placement station 14 and which carries a good component.

When the first good tray 14a is full of good components then shuttles 2b which carry a good component, which arrive into the placement station 14, will be stopped opposite to the second good tray 14b, and the handling head 3b on the respective shuttles 2b will place the respective good component into the second good tray 14b. In the meantime the first good tray 14a which is full of good components is replaced with an empty first good tray so that when the second good tray 14b is full of good components the shuttles 2b carrying good components place these good components into the empty first good tray. Likewise before the empty first good tray becomes full of good components, in the meantime, the second good tray, when full of good components, is replaced with an empty second good tray. Advantageously the assembly 1 does not need to be interrupted when a good tray at the placing station 14 becomes full of good components.

If, on the other hand, the user has selected that the assembly operate in the second mode of operation then a component which was determined at an inspection station 13a-d to have no defect (i.e. is determined to be a good component), will be placed, by the pickup head on the shuttle 2b carrying that component, into a pocket of tape at the tape station 15 (and not into one of the trays 14a, 14b in the placing station 14). Specifically, the component which was determined at an inspection station 13a-d to have a no defect (i.e. is determined to be a good component), will be placed, by the pickup head on the shuttle 2b directly into the pocket of a tape which is located at the tape station 15

In this example the tape section 15 comprises a first pre-tape module 15a, a first in-tape module 15b, and a first sealing module 15c, and a first tape 30a which has a plurality of pockets each of which can receive a component; and also a second pre-tape module 25a, a second in-tape module 25b, and a second sealing module 25c, and a second tape 30b which has a plurality of pockets each of which can receive a component.

In order for the pickup head 3b on a shuttle 2b to be able to place the component it holds into the pocket of a tape 30a, 30b, then said pocket must be in a predefined position relative to the shuttle 2b (or at least be within a predefined range of position relative to the shuttle 2b). The first and second pre-tape modules 15a, 25a each comprise a camera which is configured to detect the position of the pocket in the tape into which a component is to be placed, and to determine the position of the component on the pickup head 3b of the shuttle based on image data provided by one or more of the inspection stations 13a-d. Using this data, the first and second pre tape modules 15a, 25a can each determine the relative position of the component on the shuttle with respect to the pocket; if the relative positioning is not equal to a predefined relative positioning necessary to enable the pickup head to place the component it holds correctly into the pocket of the tape (or is not within a predefined range of relative positioning) then the location of the pocket is adjusted (e.g. by a position adjustment module which for example moves the position of the tape by scrolling the tape in either direction) so that the relative positioning is equal to the predefined relative positioning (or is within the predefined range of relative positioning). Once the tape has been moved to so as to bring the pocket into said predefined position relative to the position of the component on the pickup head 3b of the shuttle, the pickup head 3b can then place the component directly into the pocket of the tape.

The first and second in-tape modules 15b, 25b each comprise a camera which is configured to detect the position of the component in the pocket after the component has been placed into the said pocket by the pickup head 3b; the component must sit correctly (i.e. in a predefined orientation) in the pocket before the pocket is sealed. Furthermore, the camera of the first and second in-tape modules 15b, 25b is used to carry out a final inspection of the component to determine if the component has become damaged.

The first and second sealing modules 15c, 25c each comprise a means for sealing the pocket of their respective tapes 30a,b after a component has been placed into that pocket.

If a component was determined at an inspection station 13a-d to have a no defect (i.e. is determined to be a good component), and the assembly 1 is in its second mode of operation, then the shuttle 2b which is carrying that good component will be stopped opposite to the first pre-tape module 15a;

The first pre-tape module 15a will detect the position of the pocket in the first tape 30a into which the good component is to be placed (using its camera), and will determine the position of the component on the component handling head 3b of the shuttle based on image data provided by one or more of the inspection stations 13a-d. Using this data, the first pre-tape module 15a will determine the relative position of the component on the shuttle with respect to the pocket in the first tape 30a into which it is to be placed. If the relative positioning is not equal to a predefined relative positioning (or is not within a predefined range of relative positioning) then the first pre-tape module will adjust the location of the pocket (e.g. by scrolling the tape in one direction or the other) so that the position of the pocket in the first tape 30a relative to the position of the component on the pickup head 3b on the shuttle 2b, is equal to the predefined relative positioning (or is within the predefined range of relative positioning). Then the pickup head 3b on the shuttle 2b places the component directly into the pocket of the first tape 30a.

The first in-tape module 15b then checks, using its camera, the position of the component in the pocket of the first tape 30a after the component has been placed into the said pocket by the pickup head 3b. Furthermore, the first in-tape modules 15b will carry out a final inspection of the component to determine if the component has become damaged. If the component is sitting correctly in the pocket of the first tape 30a, and it is determined that the component is not damaged, then the first sealing module 15c seals the pocket.

The steps in the afore-mentioned paragraph are carried out for each good component, until all of the pockets in the first tape 30a are full. Thereafter, the good components are filled into the pockets of the second tape 30b by carrying out the same steps but using the second pre-tape module 25a, a second in-tape module 25b, and a second sealing module 25c. Of course, if the good components are to be filled into the pockets of the second tape 30b, then the respective shuttles 2b which are carrying good components will be stopped opposite to the second pre-tape module 25a (and not opposite to the first pre-tape module).

Before all of the pockets in the second tape 30b are filled with good components, in the meantime, the first tape 30a which is now full of good component, is replaced with another new first tape having empty pockets. When all of the pockets in the second tape 30b are full of good components, then components are then placed into the pockets of the new first tape; likewise before all of the pockets in the new first tape are filled with good components, the second tape which is full of good component is replaced with another new second tape having empty pockets. Advantageously the assembly 1 does not need to be interrupted when all the pockets in a tape are full of good components.

The assembly 1 further comprises a tray transporting module 31 which can automatically transport trays between a tray stacking station 35, and the picking station 12, and placing station 14, and rejection station 16. So, for example when the first good tray 14a at the placing station becomes full of good components then the tray transport module will transport that first good tray away from the placing station and will transport a new empty first tray to the placing station in replacement of the full first tray. Most preferably the tray transport module 31 handles all of the replacing of full trays or replacing of empty tray which were described in this description.

In this example the tray stacking station 36 comprises at least the following stacks: a first stack of trays 35a which comprises trays which are filled with components and which are to be passed by the transporting module 31 to the picking station; a second stack of trays 35b which comprise empty trays which the transporting module 31 has retrieved from the picking station 12; a third stack of trays 35c which comprises trays filled with defective components which the transporting module 31 has retrieved from the rejection station 16; a fourth stack of trays 35d which comprises components which are filled with good components which the transporting module 31 has retrieved from the placing station 14.

In the present invention because said shuttles 2b can be driven individually and independently of one another along the track 2a, this allows for increased operational flexibility which results in improved flow and through-put when operating the assembly 1. For example, when the first tray 12a at the picking station 12 becomes empty (because the pickup heads on the shuttles 2b which have entered the placing station have picked all of the components from the first tray 12a), then the next shuttle 2b to arrive at the picking station 12 can be stopped opposite the second tray 12b so that the pickup head on said shuttle 2b can immediately pick components from the second tray 12b (without having to wait for the first tray to be replaced with another tray full of components, or without having to wait for the second tray 12b (which is full of components) to be moved into the position which the first tray previously occupied in the picking station 12. In other words the position within the assembly at which picking of components takes place within the assembly is flexible. Similarly, the position in the assembly at which placing good components into trays at the placing station is flexible; and the position within the assembly at which placing defective components into trays at the rejection station is flexible; and the position within the assembly at which components are placed into pockets of a tape at the taping station is flexible. This flexibility allows for an increase flow in the assembly thus allowing an increased through-put to be achieved.

Various modifications and variations to the described embodiments of the invention will be apparent to those skilled in the art without departing from the scope of the invention as defined in the appended claims. Although the invention has been described in connection with specific preferred embodiments, it should be understood that the invention as claimed should not be unduly limited to such specific embodiment.

1. A component handling assembly which comprises,
a transport system which comprises,
a track, and a plurality of shuttles, wherein each of said shuttles can be driven individually and independently of one another along the track, and wherein each of said shuttles comprise at least one pick-up-head which can hold a component; and
a plurality of stations located proximate to the track, said plurality of stations comprising,
a picking station at which the pickup head on a shuttle can pick components from a tray located in said picking station;
at least one vision inspection station, which comprises one or more cameras, at which a component can be inspected;
and at least one of, a placing station at which the pickup head on a shuttle can place a component onto a tray, and/or, a tape station at which the pickup head on a shuttle can place a component into a pocket of a tape; and
wherein the assembly further comprises a vacuum system, which is configured to supply vacuum to the pickup head of each respective shuttle as said shuttles move around the track, and
wherein the vacuum system comprises,
a vacuum generating means which is operable to generate a vacuum;
a vacuum ring which defines a chamber, wherein the chamber is fluidly connected to the vacuum generating means so that vacuum generated by the vacuum generating means will create a vacuum in the chamber of the vacuum ring;
a rotatable disk which can rotate about a rotation axis, which comprises a plurality of primary conduits, each primary conduit being fluidly connected to the chamber of the vacuum ring and arranged to extend radially from the vacuum ring;
a plurality of outlets arranged at the peripheral of the rotatable disk and wherein each primary conduit is fluidly connected to a respective outlet;
a plurality of secondary conduits, wherein each secondary conduit is fluidly connected between a respective outlet and a respective shuttle so that vacuum can be supplied to the pickup head of said respective shuttle.

2. A component handling assembly according to claim 1 wherein the track is the form of a loop.

3. A component handling assembly according to claim 1 wherein the component handling assembly further comprises a rejection station at which the pickup head on a shuttle can place a component, which was determined to have a defect, onto a tray,
wherein the rejection station comprises at least two trays into which a component, which was determined to have a defect can be placed by the pickup head of a shuttle, wherein the position along the track at which the pickup head of a shuttle can place a component into one of the trays is different to the position along the track at which the pickup head of the shuttle can place a component into the other one of the trays.

4. (canceled)

5. A component handling assembly according to claim 1, wherein the picking station comprises at least two trays from which components can be picked by the pickup head on a shuttle, wherein the position along the track at which the pickup head of a shuttle can pick a component from one of the trays is different to the position along the track at which the pickup head of the shuttle can pick a component for said other one of the trays.

6. A component handling assembly according to claim 1, wherein the placing station comprises at least two trays into which a component, which is held by a pickup head on a shuttle, can be placed.

7. A component handling assembly according to claim 1, wherein the tape station comprises at least two tapes, each of which comprise pockets, into which a component, which is held by a pickup head on a shuttle, can be placed, wherein the position along the track at which the pickup head of a shuttle can place a component into a pocket of one of the tapes is different to the position along the track at which the pickup head of the shuttle can place a component into a pocket of said other one of the tapes.

8. (canceled)

9. (canceled)

10. A component handling assembly according to claim 1, wherein said at least one vision inspection station further comprises at a 2-D inspection station which comprises a camera which is used to detect the current position and current orientation of the component on the pickup head of the shuttle, and wherein images from said 2-D inspection station are used by a recentering module or by an embedded pick up head rotation system, to move the component from its current position and current orientation into a predefined position and predefined orientation on the component handling head.

11. A component handling assembly according to claim 1 wherein the tape station comprises,
a pre tape module which is configured to determine the position of the component on the pickup head relative to the position of the pocket on the tape into which the component is to be placed, and to move the tape so that the pocket is in a position in which the pickup head on the shuttle can place the component which it holds directly into the pocket of the tape;
a in-tape module which is configured check that the component which has been placed into the pocket of the tape, has a predefined orientation within the pocket; and
a sealing module which is configured to seal the pocket into which said component has been placed.

12. (canceled)

13. (canceled)

14. (canceled)

15. (canceled)

16. A component handling assembly according to claim 1, wherein the rotatable disk is configured to freewheel about the rotation axis.

17. A component handling assembly according to claim 1, wherein the vacuum system further comprises a drive motor which can drive the rotatable disk to rotate about the rotation axis.

18. (canceled)

19. A component handling assembly according to claim 1, wherein the vacuum system comprises,
a vacuum generating means which is operable to generate a vacuum;
a vacuum chamber, which is fluidly connected to the vacuum generating means, so that vacuum generated by the vacuum generating means will create a vacuum in the vacuum chamber;
a plate member having one or more openings defined therein, wherein said one or more openings are fluidly connected to the vacuum chamber.

20. A component handling assembly according to claim 19 wherein each of said plurality of shuttles comprise a sliding member which is arranged to abut a surface of the plate member and is configured to slide over said surface as the shuttle moves along the track; wherein said sliding member has a channel defined therein, where the channel has an inlet and an outlet, wherein said outlet it fluidly connected to the pickup head of the shuttle, and wherein the inlet is aligned with said one or more openings defined in the plate member, so that vacuum can be supplied to the pickup head of said shuttle as the shuttle moves around the track.

21. (canceled)

22. (canceled)

23. (canceled)

24. (canceled)

25. (canceled)

26. (canceled)

27. A component handling assembly according to claim 12, wherein the vacuum system comprises,
a vacuum generating means which is operable to generate a vacuum;
a vacuum chamber, which is fluidly connected to the vacuum generating means, so that vacuum generated by the vacuum generating means will create a vacuum in the vacuum chamber;
opposing sealing members which are elastically biased towards abutting one another to seal the vacuum chamber.

28. A component handling assembly according to claim 27, wherein each of said plurality of shuttles comprise a carriage having a stem portion and an anchoring portion, wherein the stem portion projects from the anchoring portion to between the opposing sealing members and into the vacuum chamber; the stem portion having a free end which is located in said vacuum chamber; and wherein the carriage has a channel defined therein, where the channel has an inlet defined in the free end and an outlet defined in the anchoring portion, wherein the outlet is fluidly connected to the pickup head of the shuttle, so that vacuum can be supplied to the pickup head of said shuttle as the shuttle moves around the track.

29. A component handling assembly according to claim 27, wherein the vacuum chamber is defined by an upper plate and the opposing sealing members and wherein each of the opposing sealing members have a first end which is attached to the upper plate, and a second, free end; wherein the second free ends of the opposing sealing members abut one another to seal the vacuum chamber.

30. (canceled)

31. (canceled)

32. (canceled)

33. (canceled)

34. (canceled)
